(19) United States
(12) Patent Application Publication
(10) Pub. No.: US 2026/0136849 A1
(43) Pub. Date: May 14, 2026

(54) METHODS FOR OXIDIZING A SUBSTRATE SURFACE USING GAS PHASE OXIDIZING RADICALS

(71) Applicant: Tokyo Electron Limited, Tokyo (JP)

(72) Inventors: Mengistie Debasu, Austin, TX (US); Kate Abel, Austin, TX (US)

(21) Appl. No.: 18/944,709

(22) Filed: Nov. 12, 2024

(51) Int. Cl. H01L 21/02; C23C 8/16

(52) U.S. Cl. CPC H10P 14/6308; C23C 8/16; H10P 14/6314; H10P 70/27

(57) ABSTRACT

Various embodiments of methods are provided herein for oxidizing a surface of a semiconductor substrate. In the disclosed embodiments, gas-phase oxidizing free radicals are generated and used to oxidize an exposed surface of a material and form a thin oxide film there on. The gas-phase oxidizing free radicals are generated via ultraviolet (UV) photolysis of vaporized peroxide solutions. In some embodiments, an aqueous hydrogen peroxide (H₂O₂) solution is vaporized and photolyzed with UV light to form gas-phase hydroxyl (HO*) free radicals, which oxidize the exposed surface of the material to form a thin oxide film on the exposed surface of the material.

### TECHNICAL FIELD

The present disclosure relates to semiconductor process technology for the fabrication of integrated circuits. In particular, it relates to the formation of surface and interfacial oxides on semiconductor materials, metals and gate insulators during the fabrication of integrated circuits.

### BACKGROUND

Growth of high-quality ultrathin surface and interfacial oxides on conventional semiconductor materials (such as, e.g., silicon, Si, silicon carbide, SiC, and silicon geranium, SiGe) and 2D semiconductor materials (e.g., transition metal dichalcogenides (TMDs), such as molybdenum disulfide, MoS₂) is critical and extremely challenging in the fabrication of integrated circuits with the ever-increasing device miniaturization. Interfacial oxides are needed either for the growth of high-k gate-insulators or used as gate-insulators. The quality of these oxides determines the overall performance and reliability of the final device. At present, process improvements are needed to meet performance targets for ultrathin oxide films (e.g., <2 nm) on Si gate all around (GAA) and/or 2D semiconductor channels.

Plasma, thermal, wet chemical, oxygen (O₂) and ozone (O₃)-based oxidation methods have conventionally been used to oxidize substrate surfaces and create thin oxide films on such surfaces. Plasma, thermal and wet chemical oxidation methods may be undesirable, since they are often performed at high temperature and/or pressure, or use strong oxidizers, which may damage the substrate. Current state-of-the-art methods for oxidizing silicon (Si) surfaces often use an ozonated water oxidation chemistry to grow silicon dioxide (SiO₂) films on the Si surfaces with an oxide thickness of a few nanometers. However, these methods tend to produce oxygen-deficiencies at the semiconductor/oxide interfaces, due to the larger diffusion, and continuous and nonuniform oxidation behavior of ozone (O₃).

Accordingly, it would be desirable to provide improved methods for providing high quality, ultrathin oxide films on semiconductor materials, metals and gate insulators.

### SUMMARY

The present disclosure provides various embodiments of systems and methods for oxidizing a surface of a semiconductor substrate. In the disclosed embodiments, gas-phase oxidizing free radicals are generated and used to oxidize an exposed surface of a material and form a thin oxide film there on. The gas-phase oxidizing free radicals are generated via ultraviolet (UV) photolysis of vaporized peroxide solutions. In some embodiments, an aqueous hydrogen peroxide (H₂O₂) solution is vaporized and photolyzed with UV light to form gas-phase hydroxyl (HO*) free radicals, which oxidize the exposed surface of the material to form a thin oxide film on the exposed surface of the material. As explained further herein, the very short-lifetime (˜a few ms), high oxidation potential (˜2.8 eV) and fast reactivity of the HO* free radicals enable growth of high-quality surface and interfacial oxide films on a variety of material surfaces in a controlled, quasi-self-limiting manner.

According to one embodiment, a method is provided herein for oxidizing a surface of a semiconductor substrate. In general, the method may include: (a) receiving the semiconductor substrate, the semiconductor substrate having a material exposed on the surface of the semiconductor substrate; (b) supplying a gas-phase peroxide to the surface of the semiconductor substrate; and (c) exposing the gas-phase peroxide to ultraviolet (UV) light to photolyze the gas-phase peroxide and form oxidizing radicals, which oxidize an exposed surface of the material to form an oxide film on the exposed surface of the material.

In some embodiments, a native oxide may be present on the exposed surface of the material when the semiconductor substrate is received in step (a). In such embodiments, the native oxide may be removed from the exposed surface of the material before the gas-phase peroxide is supplied to the surface of the semiconductor substrate in step (b). For example, the method may supply a cleaning solution to the semiconductor substrate to remove the native oxide from the exposed surface of the material.

A wide variety of materials may be oxidized using the method disclosed above. In some embodiments, the material being oxidized may be a silicon-containing material such as, but not limited to, silicon (Si), silicon carbide (SiC) or silicon geranium (SiGe). When utilized to oxidize a silicon-containing material, the oxidizing radicals formed in step (c) may oxidize an exposed surface of the silicon-containing material to form a silicon oxide (SiOx) film on the exposed surface of the silicon-containing material. In one example embodiment, a silicon dioxide (SiO₂) film may be formed on the exposed surface of the silicon-containing material in step (c). In other embodiments, the material being oxidized may be a metal-containing material such as, but not limited to, a transition metal, a transition metal oxide, a transition metal hydroxide, a transition metal oxyhydroxide or a transition metal dichalcogenide (TMD). When utilized to oxidize a metal-containing material, the oxidizing radicals formed in step (c) may oxidize an exposed surface of the metal-containing material to form a metal oxide film on the exposed surface of the metal-containing material or create a metal oxide film where the metal centers in that film are of a higher oxidation state compared to those in the underlying metal-containing material.

A wide variety of peroxide oxidizers can be used to generate the gas-phase peroxide supplied to surface of the semiconductor substrate 210 in step (b). In some embodiments, hydrogen peroxide (H₂O₂) may be used as the gas-phase peroxide. In such embodiments, the method may include exposing a hydrogen peroxide (H₂O₂) vapor to the UV light in step (c) to photolyze the H₂O₂ vapor and form hydroxyl radicals, which oxidize the exposed surface of the material to form the oxide film on the exposed surface of the material.

In other embodiments, the gas-phase peroxide may be an organic peroxide or a peroxy acid. When the gas-phase peroxide is an organic peroxide, the method may expose an organic peroxide vapor to the UV light in step (c) to photolyze the organic peroxide vapor and form alkoxy radicals, which may further react with water molecules to form hydroxyl radicals. When the gas-phase peroxide is a peroxy acid, the method may expose a peroxy acid vapor to the UV light in step (c) to photolyze the peroxy acid vapor and form hydroxyl radicals and acetoxy radicals. The acetoxy radicals may further react with water molecules to form additional hydroxyl radicals. In either embodiment, the hydroxyl radicals formed in step (c) may oxidize the exposed surface of the material to form the oxide film on the exposed surface of the material.

In some embodiments, the method may include one or more additional steps before providing the gas-phase peroxide to the exposed surface of the substrate. For example, the method may further include providing an aqueous peroxide solution at a temperature, and bubbling a carrier gas into the aqueous peroxide solution to vaporize the aqueous peroxide solution and generate the gas phase peroxide.

In some embodiments, the method may further include controlling a thickness of the oxide film formed on the exposed surface of the material by controlling one or more of the following: the temperature of the aqueous peroxide solution; a peroxide/water ratio in the gas-phase peroxide generated from the aqueous peroxide solution; a gas flow rate of the carrier gas provided to the aqueous peroxide solution; an intensity of the UV light; an exposure time during which the gas-phase peroxide is exposed to the UV light; and whether the gas-phase peroxide is exposed to the UV light continuously or cyclically during the exposure time.

According to another embodiment, another method is provided herein for oxidizing a surface of a semiconductor substrate. In general, the method may include: (a) receiving the semiconductor substrate, the semiconductor substrate having a silicon-containing material (e.g., silicon (Si), silicon carbide (SiC) or silicon geranium (SiGe)) exposed on the surface of the semiconductor substrate; (b) supplying a hydrogen peroxide (H₂O₂) vapor to the surface of the semiconductor substrate; and (c) exposing the hydrogen peroxide vapor to ultraviolet (UV) light to photolyze the hydrogen peroxide vapor and form hydroxyl radicals, which oxidize an exposed surface of the silicon-containing material to form an oxide film on the exposed surface of the silicon-containing material. In some embodiments, the hydroxyl radicals may oxidize the exposed surface of the silicon-containing material to form a silicon dioxide (SiO₂) film on the exposed surface of the silicon-containing material.

In some embodiments, the method may include one or more additional steps before providing the hydrogen peroxide (H₂O₂) vapor to the surface of the semiconductor substrate in step (b). For example, the method may include removing a native oxide from the exposed surface of the silicon-containing material before supplying the hydrogen peroxide vapor to the surface of the semiconductor substrate in step (b). In another example, the method may include providing an aqueous hydrogen peroxide solution at a temperature and bubbling a carrier gas into the aqueous hydrogen peroxide solution to vaporize the aqueous hydrogen peroxide solution and generate the hydrogen peroxide (H₂O₂) vapor before supplying the hydrogen peroxide vapor to the surface of the semiconductor substrate in step (b).

In some embodiments, the method may further include controlling a thickness of the oxide film formed on the exposed surface of the silicon-containing material by controlling one or more of the following: the temperature of the aqueous hydrogen peroxide solution; a hydrogen peroxide/water ratio in the hydrogen peroxide vapor generated from the aqueous hydrogen peroxide solution; a gas flow rate of the carrier gas provided to the aqueous hydrogen peroxide solution; an intensity of the UV light; an exposure time during which the hydrogen peroxide vapor is exposed to the UV light; and whether the hydrogen peroxide vapor is exposed to the UV light continuously or cyclically during the exposure time.

As noted above and described further herein, the present disclosure provides various embodiments of methods for oxidizing a surface of a semiconductor substrate. Of course, the order of discussion of the different steps as described herein has been presented for the sake of clarity. In general, these steps can be performed in any suitable order. Additionally, although each of the different features, techniques, configurations, etc., herein may be discussed in different places of this disclosure, it is intended that each of the concepts can be executed independently of each other or in combination with each other. Accordingly, the present invention can be embodied and viewed in many different ways.

Note that this Summary section does not specify every embodiment and/or incrementally novel aspect of the present disclosure or claimed inventions. Instead, the summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIG. 1 is a flowchart diagram illustrating one embodiment of a method that utilizes the techniques described herein to oxidize a surface of a semiconductor substrate.

FIG. 2 illustrates an example process flow that uses the method shown in FIG. 1.

FIG. 3 is a flowchart diagram illustrating another embodiment of a method that utilizes the techniques described herein to oxidize a surface of a semiconductor substrate.

FIG. 4 is a block diagram illustrating one embodiment of a system that uses the method shown in FIG. 3.

FIG. 5 illustrates equations depicting the formation of gas-phase hydroxyl (HO*) free radicals with ultraviolet (UV) photolysis of hydrogen peroxide (H₂O₂) vapor and the formation of silicon dioxide (SiO₂) when a silicon surface is exposed to the hydroxyl free radicals.

FIG. 6 is a table of X-ray photoelectron spectroscopy (XPS) measurement data obtained from an epitaxial silicon surface oxidized using the techniques described herein.

FIG. 7 is a graph depicting oxide thickness (expressed in nm) as a function of process time (expressed in seconds) for the XPS measurement data shown in FIG. 6.

FIG. 8 is a graph depicting the Si⁴⁺ ratio (expressed as a percentage, %) as a function of oxide thickness (expressed in nm) for the XPS measurement data shown in FIG. 6.

### DETAILED DESCRIPTION

The present disclosure provides various embodiments of systems and methods for oxidizing a surface of a semiconductor substrate. In the disclosed embodiments, gas-phase oxidizing free radicals are generated and used to oxidize an exposed surface of a material and form a thin oxide film there on. The gas-phase oxidizing free radicals are generated via ultraviolet (UV) photolysis of vaporized peroxide solutions. In some embodiments, an aqueous hydrogen peroxide (H₂O₂) solution is vaporized and photolyzed with UV light to form gas-phase hydroxyl (HO*) free radicals, which oxidize the exposed surface of the material to form a thin oxide film on the exposed surface of the material.

In some embodiments, the oxidation techniques disclosed herein can be used to form a high-quality, ultrathin (e.g., <2 nm) silicon dioxide (SiO₂) film on a silicon-containing material (e.g., a silicon (Si), silicon carbide (SiC) or silicon geranium (SiGe) material) using hydroxyl (HO*) free radicals as a gas-phase oxidizing agent. The very short-lifetime (˜a few ms), high oxidation potential (˜2.8 eV) and fast reactivity of gas-phase HO* free radicals enable growth of high-quality surface and interfacial oxide films on the exposed surfaces of the silicon-containing material in a controlled, quasi-self-limiting manner. Although demonstrated herein to form high-quality, ultrathin SiO₂ films on Si surfaces, gas-phase HO* free radicals (and other gas-phase oxidizing free radicals) can also be used to form high quality oxide films on other semiconductor materials, metals and gate insulator materials. Accordingly, the oxidation techniques disclosed herein contemplate the use of gas-phase oxidizing free radicals to oxidize a wide variety of material surfaces.

The free radicals-driven oxidation methods disclosed herein provide numerous advantages over conventional oxidation techniques. For example, the oxidation methods disclosed herein can be performed at room temperature and ambient pressure without the adverse damaging effects typically caused by conventional oxidation methods, such as plasma, thermal, wet chemical, oxygen (O₂) and ozone (O₃) based oxidations. Additionally, the free radicals-driven oxidation process is low cost and does not need expensive vacuum tooling. As a result, the free radicals-driven oxidation methods disclosed herein provide improved methods of oxidation.

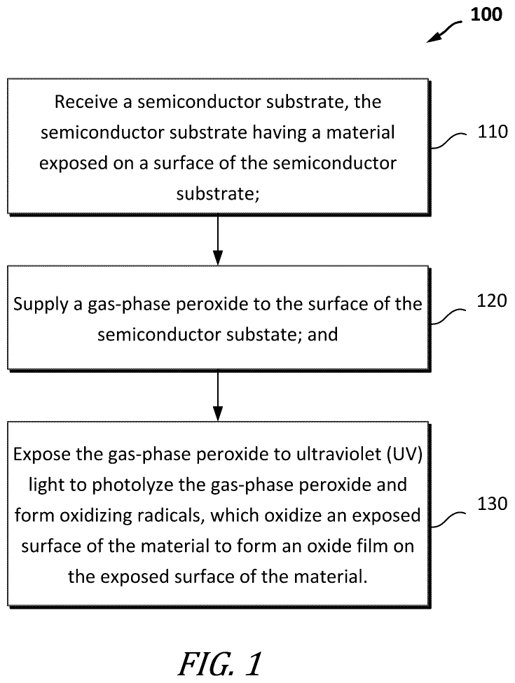

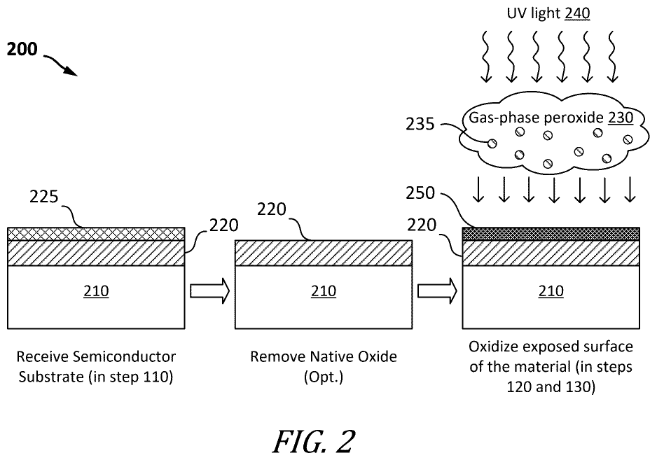

FIG. 1 illustrates one embodiment of a method 100 that utilizes the techniques disclosed herein to oxidize a surface of a semiconductor substrate, while FIG. 2 illustrates an example process flow 200 that uses the method 100 shown in FIG. 1. It will be recognized that the method 100 and the process flow 200 are merely exemplary and additional methods and process flows may utilize the techniques disclosed herein. Further, additional processing steps may be added to the method 100 and/or the process flow 200 as the steps described are not intended to be exclusive. Moreover, the order of the steps is not limited to the order shown in the figures as different orders may occur and/or various steps may be performed in combination or at the same time.

As shown in FIGS. 1 and 2, the method 100 and the process flow 200 may begin by receiving a semiconductor substrate 210 having a material 220 exposed on the surface of the semiconductor substrate (in step 110). After receiving the semiconductor substrate 210, the method 100 and the process flow 200 may supply a gas-phase peroxide 230 to the surface of the semiconductor substrate 210 (in step 120) and expose the gas-phase peroxide 230 to ultraviolet (UV) light 240 to photolyze the gas-phase peroxide 230 and form oxidizing radicals 235, which oxidize an exposed surface of the material 220 to form an oxide film 250 on the exposed surface of the material 220 (in step 130).

In some embodiments, a native oxide 225 may be present on the surface of the material 220 when the semiconductor substrate 210 is received (in step 110). In such embodiments, the native oxide 225 may be removed from the surface of the material 220 before the gas-phase peroxide 230 is supplied to the surface of the semiconductor substrate 210 (in step 120). For example, a cleaning solution (such as, e.g., dilute hydrofluoric acid, dHF) may be supplied to the semiconductor substrate 210 to remove the native oxide 225 from the exposed surface of the material 220.

A wide variety of materials 220 can be oxidized using the method 100 shown in FIG. 1 and the process flow 200 shown in FIG. 2. For example, the material 220 being oxidized may be a semiconductor material, a metal material or a gate insulator material. In some embodiments, the material 220 being oxidized may be a silicon-containing material such as, but not limited to, silicon (Si), silicon carbide (SiC) or silicon germanium (SiGe). When utilized to oxidize a silicon-containing material, the oxidizing radicals 235 formed in step 130 may oxidize an exposed surface of the silicon-containing material to form a silicon oxide (SiOx) film on the exposed surface of the silicon-containing material. In one example embodiment, a silicon dioxide (SiO₂) film may be formed in step 130.

In other embodiments, the material 220 being oxidized may be a metal-containing material, such as but not limited to, a transition metal (e.g., molybdenum (Mo), ruthenium (Ru), tungsten (W), cobalt (Co), etc.), a transition metal oxide (e.g., hafnium oxide (HfO₂), zirconium oxide (ZrO₂), cobalt oxide (CoO), molybdenum oxide (MoO₃), tungsten oxide (WO₃), ruthenium oxide (RuO₂), etc.), a transition metal hydroxide (e.g., M(OH)ₓ with M=a transition metal), a transition metal oxyhydroxide (e.g., MOₓ(OH)_{y} with M =a transition metal) or a transition metal dichalcogenide (TMD), such as molybdenum disulfide (MoS₂). When utilized to oxidize a metal-containing material, the oxidizing radicals 235 formed in step 130 may oxidize an exposed surface of the metal-containing material to form a metal oxide film on the exposed surface of the metal-containing material or create a metal oxide film where the metal centers in that film are of a higher oxidation state compared to those in the underlying metal-containing material.

A wide variety of peroxide oxidizers can be used to generate the gas-phase peroxide 230 supplied to surface of the semiconductor substrate 210 (in step 120). In some embodiments, an aqueous hydrogen peroxide (H₂O₂) solution can be vaporized to generate the gas-phase peroxide 230. Alternatively, the gas-phase peroxide 230 can be generated by vaporizing an aqueous solution containing a symmetric organic peroxide (such as, e.g., di-tert-butyl peroxide (C₈H₁₈O₂)), an asymmetric organic peroxide (such as, e.g., tert-butyl peroxybenzoate (C₁₁H₁₄O₃)), a monoperoxide (such as, e.g., tert-butyl hydroperoxide (C₄H₁₀O₂)), or a peroxy acid (such as, e.g., peracetic acid (C₂H₄O₃)). Although a wide variety of peroxide oxidizers can be used to generate the gas-phase peroxide 230, the peroxide oxidizer must be: (a) volatile, and (b) have a photon absorption spectrum where it can be photolyzed to form oxidizing radicals 235 with sufficient concentration to oxide the material surface. A wide variety of oxidizing radicals 235 may be formed in step 130, depending on the peroxide oxidizer used to generate the gas-phase peroxide 230.

In some embodiments, an aqueous hydrogen peroxide (H₂O₂) solution can be vaporized to generate a H₂O₂ vapor, which is supplied to the surface of the semiconductor substrate in step 120. The H₂O₂ vapor may then be exposed to UV light to photolyze the H₂O₂ vapor and form hydroxyl (HO*) radicals in step 130. Hydrogen peroxide undergoes photolysis most effectively at wavelengths shorter than 350 nm, meaning that it primarily absorbs and breaks down under UV light, and has an absorption maximum at about 254 nm. When H₂O₂ vapor is exposed to UV light at wavelengths ranging between about 100-300 nm, which includes UV light within the UV-C range (100-280 nm) and UV-B range (280-315 nm), each H₂O₂ molecule photolytically decomposes to generate two gas-phase hydroxyl (HO*) free radicals. The gas-phase hydroxyl (HO*) free radicals oxidize the exposed surface of the material 220 to form an oxide film on the exposed surface of the material 220 (in step 130). Because the oxidation potential (˜2.8 eV) of the gas-phase HO* free radicals is much higher than that of H₂O₂ (˜1.8 eV), the use of gas-phase HO* free radicals in the oxidation process results in a slower and more self-limiting oxide growth behavior. In addition to high oxidation potential (˜2.8 eV), the very short-lifetime (˜a few ms) and fast reactivity of the HO* radicals enable high-quality surface and interfacial oxide films to be grown on the exposed surface of the material 220 in a controlled, self-limiting manner.

In addition to H₂O₂, other peroxide oxidizers can be vaporized and photolyzed with UV light to form other types of oxidizing radicals 235 in the method 100 and process flow 200. For example, peroxy acids (such as peracetic acid (C₂H₄O₃)) can be vaporized to form a peroxy acid vapor, which form both gas-phase hydroxyl radicals and acetoxy radicals when photolyzed with UV light. On the other hand, organic peroxides can be vaporized to form an organic peroxide vapor, which forms gas-phase alkoxy radicals when photolyzed with UV light. For example, UV photolysis of di-tert-butyl peroxide (C₈H₁₈O₂) will form tert-butoxy radicals. When water vapor is present, the gas-phase acetoxy radicals and alkoxy radicals will react with water molecules in the water vapor to form an alcohol and hydroxyl radicals (HO*), which are free to oxidize the exposed surface of the material 220 to form an oxide film on the exposed surface of the material 220 (in step 130).

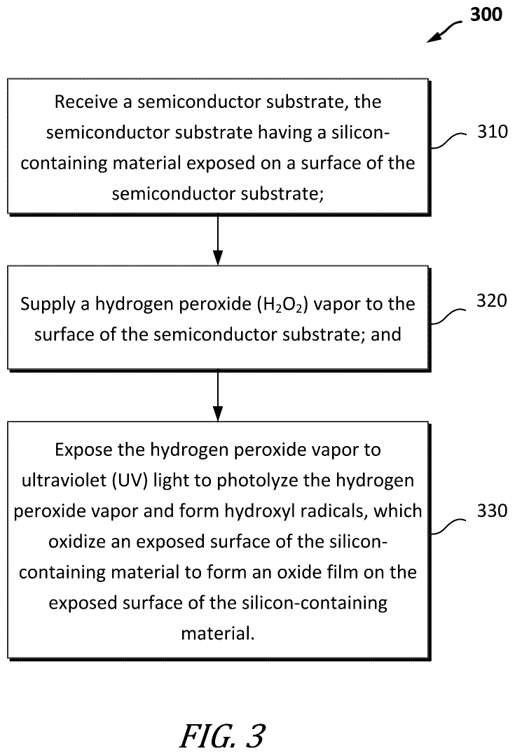

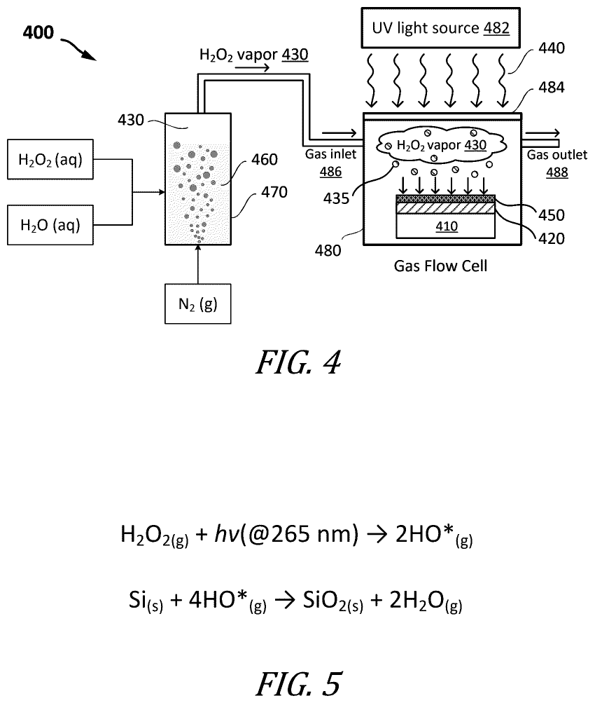

FIGS. 3 and 4 illustrate another embodiment of a method 300 and system 400 that utilize the techniques disclosed herein to oxidize a surface of a semiconductor substrate. It will be recognized that the method 300 and system 400 are merely exemplary and additional methods and systems may utilize the techniques disclosed herein. Further, additional processing steps may be added to the method 300 as the steps described are not intended to be exclusive. Moreover, the order of the steps is not limited to the order shown in the figures as different orders may occur and/or various steps may be performed in combination or at the same time.

As shown in FIGS. 3 and 4, the method 300 may begin by receiving a semiconductor substrate 410 having a silicon-containing material 420 (e.g., a Si, SiC or SiGe material) exposed on the surface of the semiconductor substrate 410 (in step 310). After receiving the semiconductor substrate 410, the method 300 may supply a hydrogen peroxide (H₂O₂) vapor 430 to the surface of the semiconductor substrate 410 (in step 320) and expose the hydrogen peroxide vapor 430 to ultraviolet (UV) light 440 to photolyze the hydrogen peroxide vapor 430 and form hydroxyl radicals 435, which oxidize an exposed surface of the silicon-containing material 420 to form an oxide film 450 on the exposed surface of the silicon-containing material 420 (in step 330). In some embodiments, a native oxide (not shown) may be removed from the surface of the silicon-containing material 420 before the hydrogen peroxide vapor 430 is supplied to the surface of the semiconductor substrate 410 (in step 320) by supplying a cleaning solution (such as, e.g., dHF) to the semiconductor substrate, as mentioned above.

The system 400 shown in FIG. 4 illustrates one example of a system that utilizes the method 300 shown in FIG. 3 to oxidize a surface of a semiconductor substrate. In the example system 400 shown in FIG. 4, an aqueous H₂O₂ solution 460 having an H₂O₂ concentration of about 5-70% is supplied to a bubbler 470 at a relatively low temperature ranging, for example, between about 20-90° C. In some embodiments, the aqueous H₂O₂ solution 460 may be provided to the bubbler 470 at approximately room temperature (e.g., 20-24° C.). A carrier gas (such as nitrogen, N₂) is bubbled into the aqueous H₂O₂ solution 460 to generate the H₂O₂ vapor 430 that is supplied to the substrate surface (in step 320). The carrier gas may be supplied to the bubbler 470 at a specified gas flow rate (e.g., 0.05-1.5 L/min or more), which is sufficient to generate the H₂O₂ vapor 430 and assist in transporting the H₂O₂ vapor 430 generated within the bubbler 470 to a flow cell 480 equipped with a UV light source 482 and UV transparent window 484. The H₂O₂ vapor 430 may enter the flow cell 480 via a gas inlet 486 and exit the flow cell 480 via a gas outlet 488, as shown in FIG. 4.

UV light 440 emitted by the UV light source 482 passes through the UV transparent window 484 to photolyze the H₂O₂ vapor 430 supplied to the flow cell 480 and generate the hydroxyl radicals 435, which oxidize the exposed surface of the silicon-containing material 420 to form the oxide film 450 on the exposed surface of the silicon-containing material 420 (in step 330). A wide variety of UV-C and UV-B light sources can be used to generate the hydroxyl radicals 435. For example, mercury (Hg) lamps and UV LED light sources can be used to provide UV light in the UV-C and UV-B wavelength range. In one embodiment, the UV light source 482 may be a UV LED light source centered at 265 nm, which is suitable for low-k dielectric environments and substrates.

Experiments were conducted to investigate the use of vaporized H₂O₂ as a precursor to generate gas-phase hydroxyl (HO*) free radicals used to oxidize an epitaxial silicon (Si) film. Prior to conducting the oxidation experiments, an epitaxial Si (epi-Si) coupon was cleaned with dilute hydrofluoric acid (dHF) solution to remove any native oxides formed on the Si surface and placed within a flow cell 480 equipped with an UV LED light source centered at 265 nm. During the oxidation experiments, a 30% (w/w) aqueous H₂O₂ solution was provided to the bubbler 470 at approximately room temperature and bubbled with nitrogen (N₂) at a gas flow rate of 1 L/min to generate H₂O₂ vapor 430, which was then transported to the flow cell 480 housing. The UV LED light source coupled to the flow cell 480 was configured to provide UV light at an intensity of about 40 mW/cm² to the H₂O₂ vapor 430 contained within the flow cell 480 housing.

As shown in FIG. 5, UV photolysis of the H₂O₂ vapor causes each H₂O₂ molecule to photolytically decompose and generate two gas-phase hydroxyl (HO*) free radicals. The gas-phase hydroxyl (HO*) radicals react with the Si surface disposed within the flow cell 480 housing to form an ultrathin (e.g., <2 nm), silicon oxide (SiOx) film on the Si surface. Water vapor is also produced as a reaction by-product. The ultrathin, SiOx film formed on the Si surface may primarily consist of silicon dioxide (SiO₂, Si⁴⁺), but may also contain other oxidation states (such as, Si⁰, S⁺, Si²⁺ and Si³⁺).

In some embodiments, the thickness of the SiOx film formed on the Si surface, and its self-limiting growth behavior, can be controlled by tuning one or more key process parameters of the oxidation process. Examples of process parameters that can be adjusted to control the thickness of the SiOx film formed on the Si surface include, but are not limited to, the temperature of the aqueous H₂O₂ solution 460 provided to the bubbler 470, the H₂O₂/H₂O ratio in the H₂O₂ vapor 430 (e.g., going from hydrous to anhydrous vapor, i.e.,1%-100% H₂O₂ vapor), the gas flow rate of the carrier gas, the intensity of the UV light, the exposure time during which the H₂O₂ vapor 430 is exposed to the UV light, the UV dose and whether the H₂O₂ vapor 430 is exposed to the UV light continuously or cyclically during the exposure time.

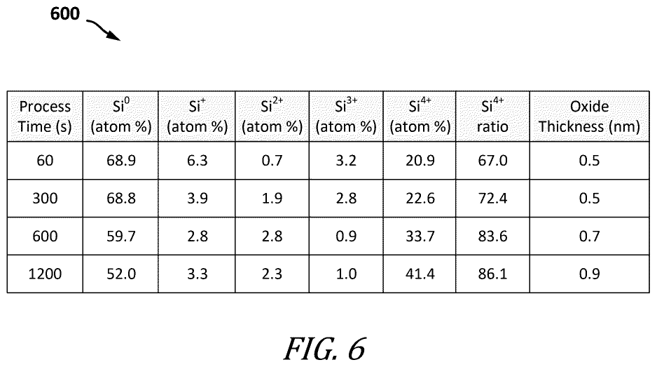

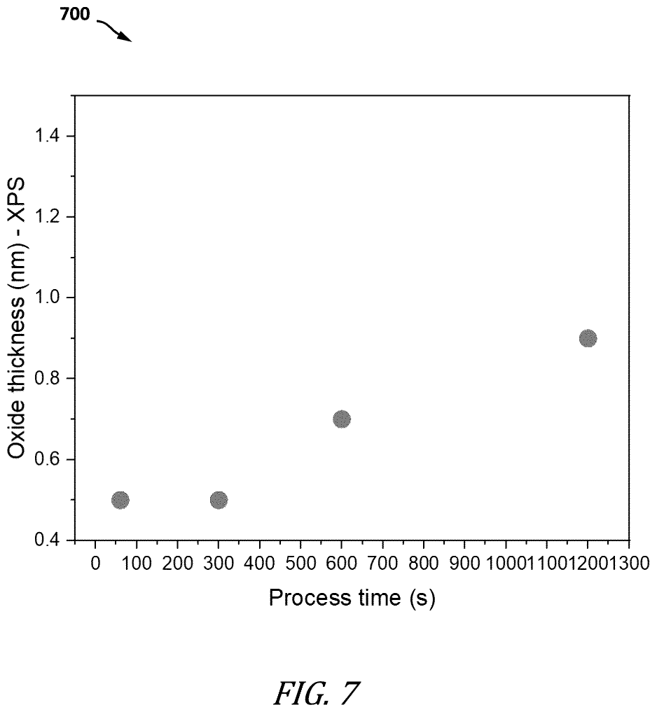

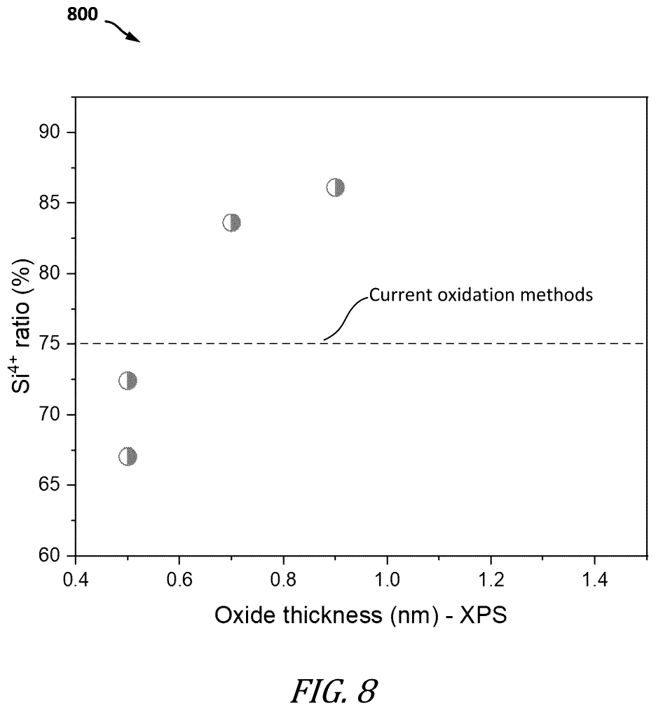

The table 600 shown in FIG. 6 depicts X-ray photoelectron spectroscopy (XPS) measurement data obtained from the oxidation experiments mentioned above over different UV exposure/process times. The graph 700 shown in FIG. 7 depicts the oxide thickness (expressed in nm) as a function of process time (expressed in seconds) for the XPS measurement data shown in FIG. 6. The graph 800 shown in FIG. 8 depicts the Si⁴⁺ ratio (expressed as a percentage, %) as a function of oxide thickness (expressed in nm) for the XPS measurement data shown in FIG. 6.

The graph 700 shows that, while the oxide thickness generally increases with UV exposure/process time, the oxidation of the Si surface with gas-phase HO* free radicals provides a relatively slow oxide growth rate of approximately 0.045 nm/min. In the oxidation experiments disclosed herein, background Si oxidation with H₂O₂ was highly suppressed by the HO* oxidation because the HO* oxidation potential (˜2.8 eV) is much higher than that of H₂O₂ (˜1.8 eV), resulting in a slower, quasi-self-limiting oxide growth behavior. Overall, the surface oxidation with gas-phase HO* free radicals was shown to provide very local, uniform and self-limiting behavior.

The graph 800 illustrates the Si⁴⁺ ratio (expressed as a percentage, %) vs. oxide thickness (expressed in nm) to investigate the quality of the oxide film formed using the techniques described herein. The Si⁴⁺ ratio is the peak intensity ratio of silicon dioxide (Si⁴⁺) to the total amount of oxides (Si⁺, Si²⁺, Si³⁺, Si⁴⁺) formed on the Si surface, and thus, provides a measure of the quality of the silicon dioxide (SiO₂) formed on the Si surface. As shown in the graph 800, the Si⁴⁺ ratio (e.g., 83.6-86.1%) obtained at oxide thicknesses of 0.7 nm and 0.9 nm is greater than the Si⁴⁺ ratio (e.g., <75%) obtained using currently available oxidation chemistry and methods, such as ozonated water, sulfuric peroxide mixture (SPM) and sulfuric acid (H₂SO₄) solutions, UV/air, etc. The greater Si⁴⁺ ratio shows how the oxidation techniques described herein can be used to enable growth of ultrathin SiO₂ films on Si surfaces with qualities exceeding those obtained using current methods.

Systems and methods for oxidizing a surface of a semiconductor substrate are described in various embodiments. In the disclosed systems and methods, a gas-phase peroxide (e.g., a vaporized hydrogen peroxide, organic oxide or peroxy acid) is used as a precursor to generate gas-phase oxidizing free radicals (e.g., gas-phase hydroxyl radicals, acetoxy radicals and/or alkoxy radicals) that react with and oxidize exposed surfaces on a semiconductor substrate. Vaporized H₂O₂ is used in the oxidation experiments discussed herein to generate gas-phase hydroxyl (HO*) free radicals used to oxidize a Si surface. Gas-phase HO* free radicals can also be generated through a reaction between alkoxy or acetoxy radicals and water vapor. As noted in the experimental results discussed above, the use of gas-phase HO* free radicals provides well-controlled, quasi-self-limiting surface oxidation (or oxide growth) on the Si surface and improves the quality of the silicon oxide film formed there on compared to conventional oxidation techniques. While demonstrated on a Si surface, the oxidation methods disclosed herein can also be used to form high quality, ultrathin surface and interface oxides on various semiconductor materials, metals and gate insulator materials.

The free radicals-driven oxidation process disclosed herein provides additional advantages over conventional oxidation techniques. For example, the oxidation process disclosed herein can be performed at ambient pressure and room temperature using green and gentle oxidizing chemistry with commonly used oxidizing precursors and reagents in the semiconductor process (e.g., air, N₂, H₂O, and H₂O₂). As such, the oxidation process disclosed herein can be used to oxidize an exposed substrate surface without the adverse damaging effects typically caused by conventional oxidation methods, such as plasma, thermal, wet chemical, oxygen (O₂) and ozone (O₃) based oxidations. Additionally, the free radicals-driven oxidation process is low cost, and does not need expensive vacuum tooling.

The term “semiconductor substrate” or “substrate” as used herein means and includes a base material or construction upon which materials are formed. It will be appreciated that the substrate may include a single material, a plurality of layers of different materials, a layer or layers having regions of different materials or different structures in them, etc. These materials may include semiconductors, insulators, conductors, or combinations thereof. For example, the substrate may be a semiconductor substrate, a base semiconductor layer on a supporting structure, a metal electrode or a semiconductor substrate having one or more layers, structures or regions formed thereon. The substrate may be a conventional silicon substrate or other bulk substrate comprising a layer of semi-conductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

The substrate may also include any material portion or structure of a device, particularly a semiconductor or other electronics device, and may, for example, be a base substrate structure, such as a semiconductor substrate or a layer on or overlying a base substrate structure. Thus, the term “substrate” is not intended to be limited to any particular base structure, underlying layer or overlying layer, patterned layer or unpatterned layer, but rather, is contemplated to include any such layer or base structure, and any combination of layers and/or base structures.

It is noted that reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Further modifications and alternative embodiments of the methods described herein will be apparent to those skilled in the art in view of this description. It will be recognized, therefore, that the described methods are not limited by these example arrangements. It is to be understood that the forms of the methods herein shown and described are to be taken as example embodiments. Various changes may be made in the implementations. Thus, although the inventions are described herein with reference to specific embodiments, various modifications and changes can be made without departing from the scope of the present inventions. Accordingly, the specification and figures are to be regarded in an illustrative rather than a restrictive sense, and such modifications are intended to be included within the scope of the present inventions. Further, any benefits, advantages, or solutions to problems that are described herein with regard to specific embodiments are not intended to be construed as a critical, required, or essential feature or element of any or all the claims.

What is claimed is:

1. A method for oxidizing a surface of a semiconductor substrate, the method comprising:
receiving the semiconductor substrate, the semiconductor substrate having a material exposed on the surface of the semiconductor substrate;
supplying a gas-phase peroxide to the surface of the semiconductor substrate; and
exposing the gas-phase peroxide to ultraviolet (UV) light to photolyze the gas-phase peroxide and form oxidizing radicals, which oxidize an exposed surface of the material to form an oxide film on the exposed surface of the material.

2. The method of claim 1, wherein the gas-phase peroxide is hydrogen peroxide (H₂O₂), and wherein said exposing the gas-phase peroxide to the UV light comprises:
exposing a hydrogen peroxide (H₂O₂) vapor to the UV light to photolyze the H₂O₂ vapor and form hydroxyl radicals, which oxidize the exposed surface of the material to form the oxide film on the exposed surface of the material.

3. The method of claim 2, wherein the material is a silicon-containing material.

4. The method of claim 3, wherein the silicon-containing material is silicon (Si), silicon carbide (SiC) or silicon geranium (SiGe).

5. The method of claim 3, wherein the hydroxyl radicals oxidize the exposed surface of the silicon-containing material to form a silicon dioxide (SiO₂) film on the exposed surface of the silicon-containing material.

6. The method of claim 2, wherein the material is a metal-containing material.

7. The method of claim 6, wherein the metal-containing material is a transition metal, a transition metal oxide, a transition metal hydroxide, a transition metal oxyhydroxide or a transition metal dichalcogenide (TMD).

8. The method of claim 7, wherein the hydroxyl radicals oxidize the exposed surface of the metal-containing material to form a metal oxide film on the exposed surface of the metal-containing material.

9. The method of claim 1, wherein the gas-phase peroxide is an organic peroxide, and wherein said exposing the gas-phase peroxide to the UV light comprises:
exposing an organic peroxide vapor to the UV light to photolyze the organic peroxide vapor and form alkoxy radicals, which react with water molecules to form hydroxyl radicals, wherein the hydroxyl radicals oxidize the exposed surface of the material to form the oxide film on the exposed surface of the material.

10. The method of claim 1, wherein the gas-phase peroxide is a peroxy acid, and wherein said exposing the gas-phase peroxide to the UV light comprises:
exposing a peroxy acid vapor to the UV light to photolyze the peroxy acid vapor and form hydroxyl radicals and acetoxy radicals, wherein the acetoxy radicals react with water molecules to form hydroxyl radicals, which oxidize the exposed surface of the material to form the oxide film on the exposed surface of the material.

11. The method of claim 1, wherein before supplying the gas-phase peroxide to the surface of the semiconductor substrate, the method further comprises:
removing a native oxide from the exposed surface of the material.

12. The method of claim 11, wherein said removing the native oxide from the exposed surface of the material comprises:
supplying a cleaning solution to the semiconductor substrate to remove the native oxide from the exposed surface of the material.

13. The method of claim 1, wherein before providing the gas-phase peroxide to the exposed surface of the substrate, the method further comprises:
providing an aqueous peroxide solution at a temperature; and
bubbling a carrier gas into the aqueous peroxide solution to vaporize the aqueous peroxide solution and generate the gas phase peroxide.

14. The method of claim 13, further comprising controlling a thickness of the oxide film formed on the exposed surface of the material by controlling one or more of the following:
the temperature of the aqueous peroxide solution;
a peroxide/water ratio in the gas-phase peroxide generated from the aqueous peroxide solution;
a gas flow rate of the carrier gas provided to the aqueous peroxide solution;
an intensity of the UV light;
an exposure time during which the gas-phase peroxide is exposed to the UV light; and
whether the gas-phase peroxide is exposed to the UV light continuously or cyclically during the exposure time.

15. A method for oxidizing a surface of a semiconductor substrate, the method comprising:
receiving the semiconductor substrate, the semiconductor substrate having a silicon-containing material exposed on the surface of the semiconductor substrate;
supplying a hydrogen peroxide (H₂O₂) vapor to the surface of the semiconductor substrate; and
exposing the hydrogen peroxide vapor to ultraviolet (UV) light to photolyze the hydrogen peroxide vapor and form hydroxyl radicals, which oxidize an exposed surface of the silicon-containing material to form an oxide film on the exposed surface of the silicon-containing material.

16. The method of claim 15, wherein the silicon-containing material is silicon (Si), silicon carbide (SiC) or silicon geranium (SiGe).

17. The method of claim 15, wherein the hydroxyl radicals oxidize the exposed surface of the silicon-containing material to form a silicon dioxide (SiO₂) film on the exposed surface of the silicon-containing material.

18. The method of claim 15, wherein before supplying the hydrogen peroxide vapor to the surface of the semiconductor substrate, the method further comprises:
removing a native oxide from the exposed surface of the silicon-containing material.

19. The method of claim 15, wherein before supplying the hydrogen peroxide (H₂O₂) vapor to the exposed surface of the semiconductor substrate, the method further comprises:
providing an aqueous hydrogen peroxide solution at a temperature; and
bubbling a carrier gas into the aqueous hydrogen peroxide solution to vaporize the aqueous hydrogen peroxide solution and generate the hydrogen peroxide (H₂O₂) vapor.

20. The method of claim 19, further comprising controlling a thickness of the oxide film formed on the exposed surface of the silicon-containing material by controlling one or more of the following:
the temperature of the aqueous hydrogen peroxide solution;
a hydrogen peroxide/water ratio in the hydrogen peroxide vapor generated from the aqueous hydrogen peroxide solution;
a gas flow rate of the carrier gas provided to the aqueous hydrogen peroxide solution;
an intensity of the UV light;
an exposure time during which the hydrogen peroxide vapor is exposed to the UV light; and
whether the hydrogen peroxide vapor is exposed to the UV light continuously or cyclically during the exposure time.
